(19) United States
(12) Patent Application Publication
(10) Pub. No.: US 2004/0041990 A1
(43) Pub. Date: Mar. 4, 2004

(54) System and method for using flexographic media in an imaging system

(76) Inventor: John W. Wolber, Nashua, NH (US)

Correspondence Address: Agfa Corporation, Law & Patent Department, 200 Ballardvale Street, Wilmington, MA, 01887-1069, US

(21) Appl. No.: 10/230,585

(22) Filed: Aug. 29, 2002

(51) Int. Cl. G03F 7/24; G03F 7/26; B41C 1/18

(52) U.S. Cl. 355/27; 430/306; 430/309; 430/273.1; 430/300

(57) ABSTRACT

An imaging system is disclosed for imaging and photo-processing flexographic media. The imaging system includes an input opening through which flexographic media may be input to the imaging system, an imaging unit, a photo-processing unit, and an output opening. The imaging unit is for imaging the flexographic media that is received through the input opening, and provides imaged flexographic media. The photo-processing unit receives the imaged flexographic media, and photo-processes the imaged flexographic media by illuminating the flexographic media. The photo-processing unit provides photo-processed imaged flexographic media. The photo-processed imaged flexographic media may exit the imaging system through the output opening.

### BACKGROUND OF THE INVENTION

The invention generally relates to the field of imaging systems, and specifically relates to systems and methods for recording and processing flexographic plates in pre-press imaging

In many pre-press imaging systems, such as imagesetters or platesetters, a plurality of sheets or plates (hereafter referred to as plates) of flexographic recording media are separately exposed by an imaging source. The flexographic media may include sheets of a photo-polymerizable material. Each plate may provide a pattern for a different color (e.g., yellow, magenta, cyan and possibly black), and these plates must be registered with one another during printing of the final multi-color image. The flexographic recording media to be imaged by a pre-press imaging system may be supplied in web form or in discrete plates.

During imaging, a movable optical carriage is typically used to displace a laser system or other imaging source in a slow scan direction along a stationary or moving, curved or planar, media support surface (e.g., an external drum, and internal drum, a flatbed, or other support surface). The imaging source exposes a supply or recording media supported on, and held against, the media support surface. Generally, the imaging source includes an optical system for scanning one or more lasers or other radiation beams, each modulated by a digital information signal, over the recording media to record an image onto the recording media. Generally, the information signal is recorded onto a supply of recording media mounted about the external drum by displacing the imaging source relative to the media support surface, e.g., an external drum. This may be accomplished in a number of ways, including rotation of the external drum in combination with a lateral translation of the imaging source, etc. In certain systems, the external drum is rotated while the imaging source is displaced in discrete steps or continuously along the length of the external drum to record data onto the recording media.

The imaged flexographic plate is then output from the imaging system, and transported to a photo-processing station, where the photo-polymers of the flexographic plate are photo-cured. The flexographic plate is then transported to a chemical processing station in which the non-desired portions of the image are removed from the surface of the plate to form the flexographic relief image for printing.

The use of a separate photo-processing and chemical processing stations require additional floor space as well as handling and separate processing steps, which increase the risk of occurrence of human and other errors. It is desirable to reduce the processing time and to reduce the chance of error in the processing operations in flexographic imaging systems.

There is a need, therefore, for an improved system and method for imaging and processing flexographic media in a pre-press imaging system.

### SUMMARY OF THE INVENTION

The invention provides an imaging system is disclosed for imaging and photo-processing flexographic media. The imaging system includes an input opening through which flexographic media may be input to the imaging system, an imaging unit, a photo-processing unit, and an output opening. The imaging unit is for imaging the flexographic media that is received through the input opening, and provides imaged flexographic media. The photo-processing unit receives the imaged flexographic media, and photo-processes the imaged flexographic media by illuminating the flexographic media. The photo-processing unit provides photo-processed imaged flexographic media. The photo-processed imaged flexographic media may exit the imaging system through the output opening.

### BRIEF DESCRIPTION OF THE DRAWINGS

The following description may be further understood with reference to the accompanying drawings in which:

FIG. 1 shows an illustrative isometric view of an external drum imaging system of the invention together with an output table;

FIG. 2 shows an illustrative isometric view of the imaging system of FIG. 1 in accordance with an embodiment of the invention with the housing removed;

FIG. 3 shows an illustrative side view of the imaging system of FIG. 1 with the housing removed;

FIG. 4 shows an illustrative bottom view of the photo-processing unit of FIG. 3 taken along line 4-4 thereof;

FIG. 5 shows a diagrammatic flow chart of an imaging and photo-processing system of the invention;

FIGS. 6A-6D show diagrammatic illustrations of various steps in the photo-processing system of the invention; and

FIG. 7 shows an illustrative side view of the imaging system of a further embodiment of the invention with the housing removed.

The drawings are shown for illustrative purposes only, and are not to scale.

### DETAILED DESCRIPTION OF THE INVENTION

An embodiment of a system of the invention is illustrated in the accompanying drawings, wherein like reference numerals refer to like elements throughout the drawings. Although the drawings are intended to illustrate an embodiment of the present invention, the drawings are not necessarily drawn to scale.

A flexographic media processing system of the invention may be used with an external drum imaging system that is configured to record digital data onto a flexographic printing plate.

Although described below with regard to an external drum flexographic platesetter, many aspects of the present invention may be used in conjunction with a wide variety of other types of flexographic external drum, internal drum, sleeve or flatbed imaging systems, including imagesetters and the like, without departing from the intended scope of the present invention.

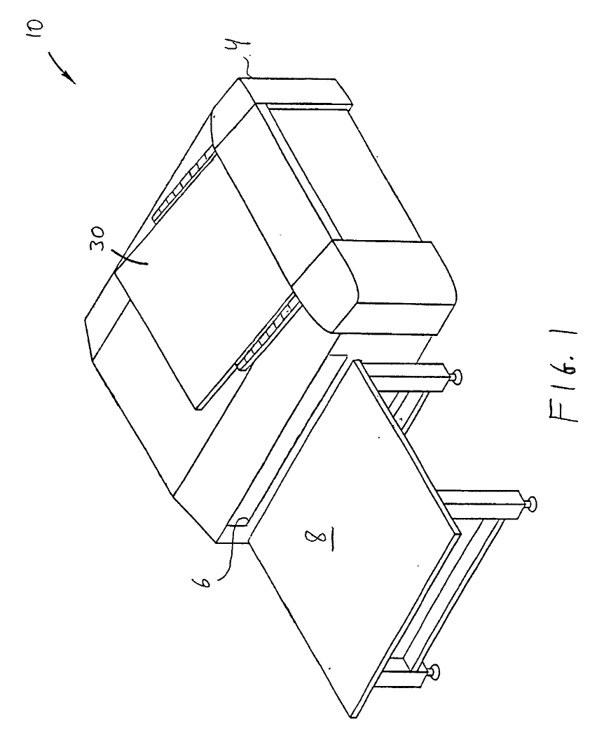

As shown in FIG. 1, in accordance with an embodiment of the invention, a flexographic plate may be placed onto an input tray 30 of an image recorder, such as a platesetter 10 having a housing 4. The flexographic plate is then imaged, and then photo-processed inside the platesetter 10 in accordance with the invention. The flexographic plate is then output from the platesetter 10 via output port 6 and deposited onto a table 8 in the illustrated embodiment.

The imaging system generally includes a front end computer or workstation (not shown) for the design, layout, editing, and/or processing of digital files representing pages to be printed, a raster image processor (RIP) for further processing the digital pages to provide rasterized page data (e.g., rasterized digital files) for driving an image recorder, and the platesetter 10, for recording the rasterized digital files onto a printing plate or other recording media. The platesetter 10 records the digital data provided by the RIP onto a supply of flexographic media including a photo-ablatable surface. In the present embodiment, the flexographic printing plate is manually loaded onto a staging area of the platesetter 10 by an operator. Alternately, or in addition to manual loading, the flexographic plate may be provided and loaded onto the platesetter 10 by a media supply or autoloading system, which may accept a plurality of the same size or different size flexographic printing plates.

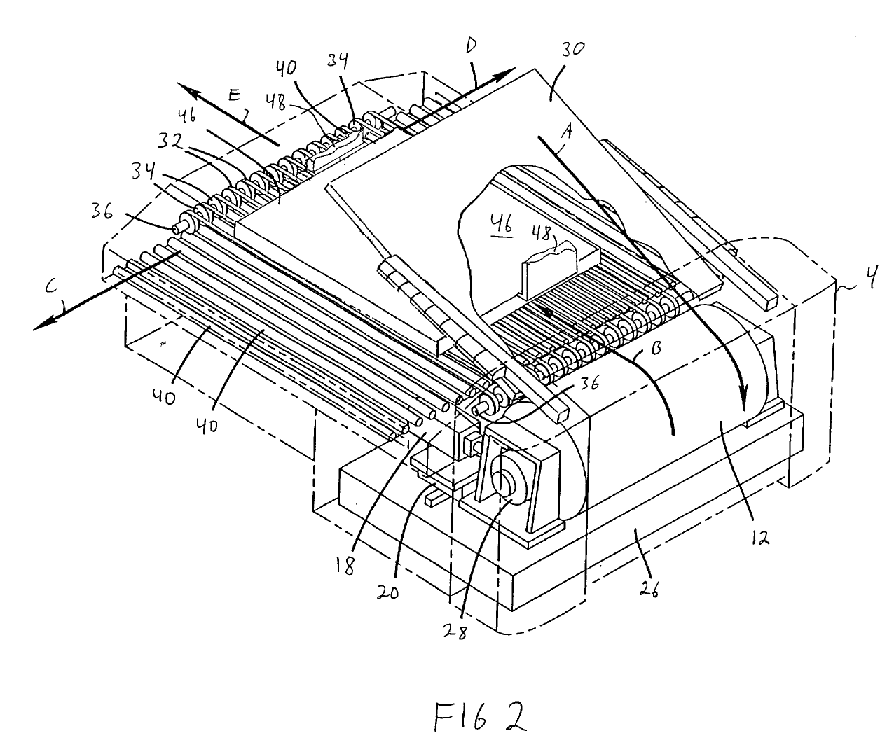

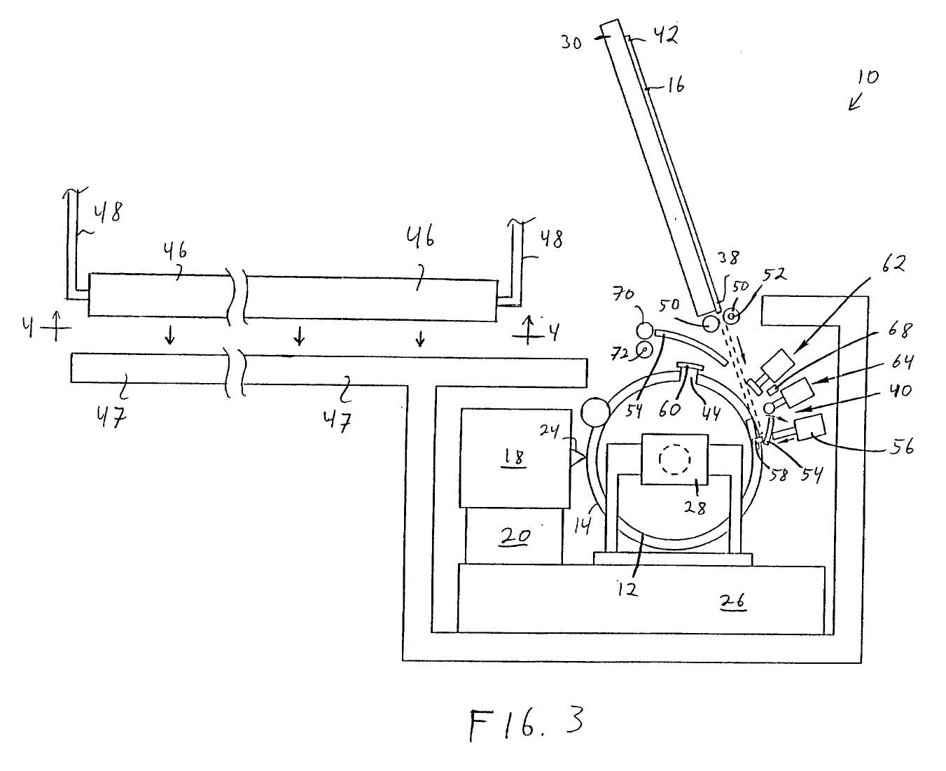

As shown in FIG. 2, the platesetter 10 includes an external drum 12 having a cylindrical media support surface 14 for supporting the flexographic printing plate 16 (shown in FIG. 3) during imaging. The external drum platesetter 10 further includes a scanning system 18, coupled to a movable carriage 20, for recording digital data onto the imaging surface 22 of the printing plate 16 using a single or multiple imaging beams 24 (shown in FIG. 3). The carriage 20 rides along a stable base 26, and the drum 12 rotates about a drum drive system 28. The base 26 may be formed of heavy material, such as a polymer-concrete mixture, granite, or the like, to vibrationally isolate the external drum 12 and scanning system 18 from external vibrations.

The flexographic platesetter 10 also includes a photo-processing source 46 that is suspended above the output area of the imaging system by suspension brackets 48 as shown in FIGS. 2 and 3. Generally, during use a plate is positioned on an input tray 30, and transferred to an imaging area in a direction as indicated at A. After imaging, the plate is transferred from the imaging area to the output area in a direction as indicated at B using transfer belts 32 that are driven by pulleys 34 about pulley shafts 36. From the output area, the plate may be photo-processed as discussed below in further detail. The plate may then be exited from the platesetter 10 in either of a direction as indicated at C or a direction as indicated at D by rollers 40 that contact the plate after the pulleys 34 and belts 32 are lowered with respect to the rollers 40. In other embodiments, the plate may be output in a direction as indicated at E by the pulleys 34 and belts 32.

As shown in FIG. 3, the scanning system 18 is displaced by the movable carriage 20 in a slow scan (axial) direction along the length of the rotating external drum 12 to expose the printing plate 16 in a line-wise manner when a single beam is used or in a section-wise manner for multiple beams. Other types of imaging systems may also be used in the present invention. In an embodiment, the printing plate 16 is loaded onto the external drum 12 while rotating the drum in a first clockwise direction. The external drum 12 is then rotated by a drive system 28 in a clockwise or counterclockwise fast scan direction, typically at a rate of about 100-1000 rpm. The printing plate 16 is then imaged while the drum is rotated in the fast scan direction. Finally, the printing plate 16 is unloaded from the external drum 12 while rotating the drum in the second direction.

In accordance with the embodiment of the invention shown in FIGS. 1-3, the system also includes a photo-processing station 46 within the imaging system 10. As will be discussed in further detail below, the photo-processing station processes the flexographic plates to set (or selectively harden) the photo polymers in the flexographic media.

As shown in FIG. 3, the flexographic plate 16 is positioned on the input tray 30 above a pair of resilient input nip rollers 50, one of which may be driven by a drive assembly 52. The leading edge 38 of the plate 16 is positioned by the input tray 30 to rest substantially between the input nip rollers 50. The rollers 50 are positioned above the external drum 12, and are oriented such that the common tangent of the rollers 50 is tangent to the media support surface 14. The input tray 30 is oriented such that the loading path of the plate 16 extends along a line that is tangent to the external drum 12 at a leading edge clamping mechanism 40.

A curved input/output guide platen 54, mounted to a frame member (not shown) of the external drum platesetter 10 may be provided to direct the leading edge 38 of the printing plate 16 toward the leading edge clamping mechanism 40 during the loading of the printing plate 16 onto the external drum 12. In addition, the curved input/output guide platen 54 is configured to direct the printing plate 16 off of the external drum 12 toward the plate output area after imaging is complete.

During loading of the plate 16, the drum 12 is rotated until the leading edge clamping mechanism 40 is positioned to receive the leading edge 38 of the plate 16. A clamping portion 54 of the clamping mechanism 40 is held in an open position by an actuator 56, exposing registration pins 58. A trailing edge clamping mechanism 44 is rotated by the drive system 28, if necessary, to position a clamping bar 60 out of the way of the loading path of the plate 16. An actuation system 62 for the trailing edge clamping mechanism 44, and an ironing roller system 64, may also be retracted away from the media support surface 14 of the external drum 12 out of the way of the loading path. After the leading edge 38 of the plate 16 is properly positioned against the registration pins 58, the leading edge clamping mechanism is closed, thereby pinching the plate 16 against the external drum 12 while the leading edge 38 remains in contact with the registration pins 58.

After the leading edge clamping operation, the external drum 12 is rotated a few degrees by the drive system 28. The ironing roller assembly of the stationary ironing roller system 64 is then extended and positioned against the plate 16 by an actuating system. The plate is drawn around the drum 12 until the trailing edge 42 of the plate 16 is positioned adjacent the trailing edge clamping mechanism 44. The clamping bar 60 is then positioned over the trailing edge 42 of the plate 16. If the size of the plate is not known and pre-programmed into the system, a sensor 68 may be used to detect the trailing edge of the plate 16. The drum and clamping bar 60 are then rotated together, and the clamping bar 60, which is normally biased away from the drum 12, is then forced against the drum 12 by the actuation system 62. Vacuum may also be used to facilitate securing the plate to the drum.

During imaging, the leading edge 38 of the plate 16 is held in position against the media support surface 14 by the leading edge clamping mechanism 40. Similarly, the trailing edge 42 of the printing plate 16 is held in position against the media support surface 14 by the trailing edge clamping mechanism 44. Both the trailing edge clamping mechanism 44 and the leading edge clamping mechanism 40 provide a tangential friction force between the printing plate 16 and the external drum 12 sufficient to resist the tendency of the edges of the printing plate 16 to pull out of the clamping mechanisms 40, 44, at a high drum rotational speed. In accordance with the present invention, only a small section (e.g., 6 mm) of the leading and trailing edges 38, 42, is held against the external drum 12 by the leading and trailing edge clamping mechanisms 40, 44, thereby preserving as much of the available imaging area of the printing plate 16 as possible.

During output of the plate 16 from the drum 12, the drive system 28 rotates the drum 12 in a counterclockwise direction, the trailing edge clamping mechanism 44 is released, and the leading edge clamping mechanism 40 is released. The trailing edge 42 of the plate 16 is guided by the input/output platen 54 toward resilient output nip rollers 70, one of which may include a drive system 72. The plate 16 is then received in the output area by the belts 32 which are rotated about pulleys 34 in a direction that causes the top surface of the belts 32 to travel with the plate as it emerges from the imaging area, and thereby carry the plate away from the imaging area.

Once the plate reaches an optionally retractable stop surface, the plate stops moving and the drive system for the pulleys 34 is turned off. In other embodiments, plate advancement may cease responsive to the output of a position sensor in the output area.

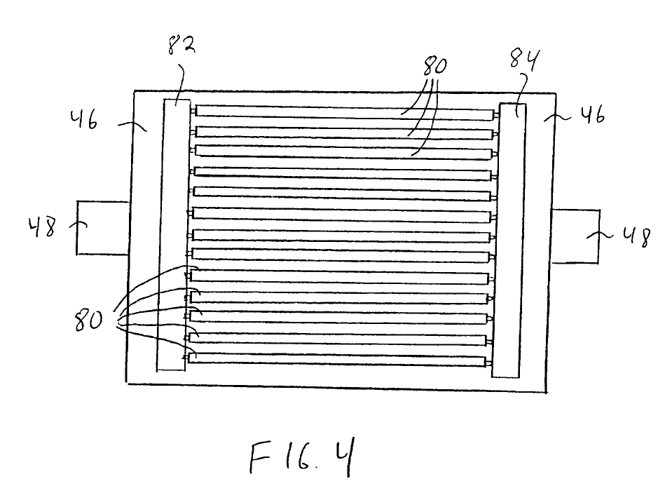

As shown in FIGS. 3 and 4, the output area also includes the photo-processing illumination source 46, which includes a plurality of elongated illumination tubes 80 that are connected in parallel via tracks 82 and 84. The illumination source 46 is suspended above the belts 40 via brackets 48 with sufficient elevation to permit a flexographic plate to be received in the output area on the belts 40 underneath the source 46.

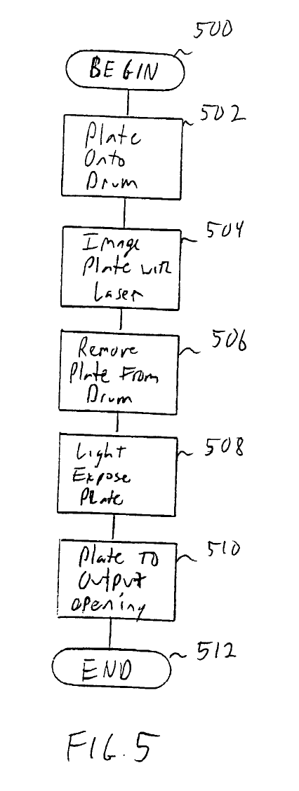

As shown in FIG. 5, the imagesetter of the present embodiment begins the imaging and photo-processing system (step 500) by transferring a flexographic plate onto an external drum (step 502). The system then images the plate while the plate is on the drum using an illumination source such as a laser (step 504). The system then removes the plate from the drum and transfers the plate to an output area (step 506). The system then exposes the entire plate with a flexographic illumination source (step 508), and then outputs the plate to an output opening (step 510) before ending (step 512).

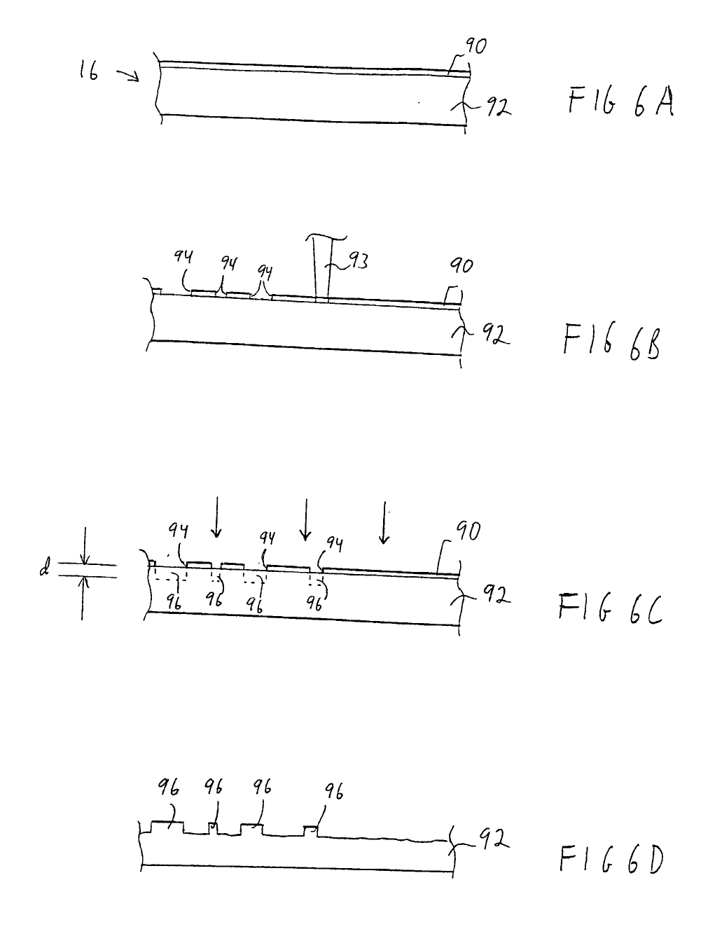

In particular, and with reference to FIGS. 6A-6D, the flexographic plate 16 includes a thin layer of a carbon material 90, which may be easily ablated by the writing laser 26, and a photopolymer layer 92. As shown in FIG. 6B, when the illumination field 93 from the writing laser 26 contacts the plate 16 in the imaging area, the carbon film is ablated by the laser beam as indicated at 94. After imaging, the plate is removed from the imaging area, and output to an output area underneath the photo-processing illumination source 46. The selectively ablated carbon film then acts as a mask during the photo-processing step. Specifically, the illumination field 95 from the illumination source 46 then exposes the portions 96 of the photo-polymer 92 that are associated with the ablated portions of the carbon film, leaving the adjacent portions of the photo-polymer un-exposed. The exposed portions 96 of the photo-polymer film 92, therefore, become photo-cured and harden to a certain depth as indicated at d as shown in FIG. 6C. Later, the plate may be chemically processed to remove the remaining carbon film as well as the un-cured portions of the plate to a depth again of about d as shown in FIG. 6D to form the final imaged and fully processed flexographic plate. In certain embodiments, the other side of the film (the side that is not imaged) may be photo-cured (or hardened) using an illumination source similar to 46 with no carbon film. This produces a final imaged flexographic plate with additional structural rigidity, and this step may be performed either before or after imaging and photo-processing by the platesetter 10.

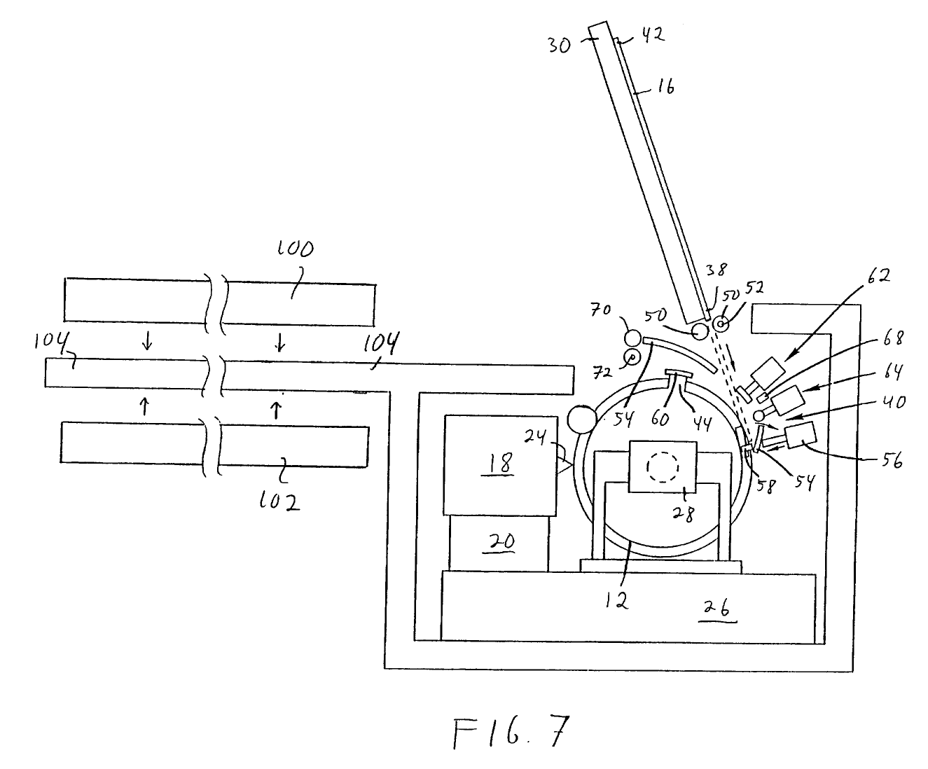

In a further embodiment, a system of the invention may include two illumination sources 100 and 102 similar to source 46 discussed above, one above and one below the imaging output area 104 as shown in FIG. 7. The output area 104 may include belts similar to belts 32 that are discussed above with reference to FIG. 2 except that they must be formed of a clear material. The output area 104 may also include rollers similar to rollers 40 discussed above with reference to FIG. 2.

The system shown in FIG. 7 provides that both sides of a flexographic plate maybe photo-processed processed inside the platesetter, either simultaneously of sequentially. As discussed above, this permits the back (non-imaged) side of the flexographic plate to become photo-cured. If the output area 104 includes rollers similar to rollers 40 discussed above, then the process of photo-curing the non-imaged side of the flexographic plate should involve actuating the rollers during the photo-curing process to move the plate small amount equivalent to about one half of a rotation of the rollers. This will ensure that the non-imaged side of the plate will be uniformly photo-cured.

Those skilled in the art will appreciate that numerous modifications and variations may be made to the above disclosed embodiments without departing from the spirit and scope of the present invention.

What is claimed is:

1. An imaging system for imaging and photo-processing flexographic media, said imaging system comprising:
an input opening through which flexographic media may be input to said imaging system;
an imaging unit for imaging said flexographic media that is received through said input opening, said imaging unit providing imaged flexographic media;
a photo-processing unit for receiving said imaged flexographic media, and for photo-processing said imaged flexographic media by illuminating said flexographic media, said photo-processing unit providing photo-processed imaged flexographic media; and
an output opening through which said photo-processed imaged flexographic media may exit said imaging system.

2. An imaging system as claimed in claim 1, wherein said photo-processing unit includes an array of tubular sources of illumination.

3. An imaging system as claimed in claim 1, wherein said photo-processing unit is suspended above said imaged flexographic media when said imaged flexographic media is received by said photo-processing unit.

4. An imaging system as claimed in claim 1, wherein said photo-processing unit is suspended above and supported below said imaged flexographic media when said imaged flexographic media is received by said photo-processing unit.

5. An imaging system as claimed in claim 1, wherein said photo-processing unit receives said imaged flexographic media from said imaging unit via an imaging output surface along a linear path.

6. A pre-press flexographic imaging system for imaging and photo-processing flexographic media, said flexographic imaging system comprising:
an external drum imaging system for imaging flexographic media and producing imaged flexographic media, said flexographic media including a film of opaque material on the exposed surface of said flexographic media, and said imaging system providing that portions of said opaque material may be ablated during imaging such that first portions of said flexographic media may be exposed beneath said opaque material during imaging; and
a photo-processing unit for receiving said imaged flexographic media and producing photo-processed imaged flexographic media, said photo-processing unit providing that said first portions of said imaged flexographic media may be photo-cured by said photo-processing unit.

7. A pre-press imaging system as claimed in claim 6, wherein said photo-processing unit is positioned above said imaged flexographic media when said imaged flexographic media is received by said photo-processing unit.

8. A pre-press imaging system as claimed in claim 1, wherein said photo-processing unit is suspended above and supported below said imaged flexographic media when said imaged flexographic media is received by said photo-processing unit.

9. A pre-press imaging system as claimed in claim 1, wherein said photo-processing unit receives said imaged flexographic media from said imaging unit via an imaging output surface along a linear path.

10. An imaging system for imaging and photo-processing flexographic media, said imaging system comprising:
input means for receiving flexographic media input to said imaging system;
imaging means for imaging said flexographic media and for providing imaged flexographic media;
photo-processing means photo-processing said imaged flexographic media, and for providing photo-processed imaged flexographic media; and
output means for providing that said photo-processed imaged flexographic media may exit said imaging system.

11. An imaging system as claimed in claim 10, wherein said photo-processing means includes suspension brackets and is suspended above said imaged flexographic media when said imaged flexographic media is received by said photo-processing means.

12. An imaging system as claimed in claim 10, wherein said photo-processing means is positioned above and positioned below said imaged flexographic media when said imaged flexographic media is received by said photo-processing means.

13. An imaging system as claimed in claim 10, wherein said photo-processing means receives said imaged flexographic media from said imaging means via an imaging output surface along a linear path.

14. A method of imaging and photo-processing flexographic media in an imaging system, said method comprising the steps of:
receiving flexographic media via an input opening in said imaging system;
imaging said flexographic media to provide imaged flexographic media;
photo-processing said imaged flexographic media to provide photo-processed imaged flexographic media; and
outputting photo-processed imaged flexographic media from said imaging system.

15. A method as claimed in claim 14, wherein said step of imaging said flexographic media includes ablating a portion of a layer of opaque material on the exposed surface of said flexographic media.

16. A method as claimed in claim 14, wherein said step of photo-processing said imaged flexographic media includes the step of illuminating said imaged flexographic media with an illumination source that is positioned above said imaged flexographic media.

17. A method as claimed in claim 14, wherein said step of photo-processing said imaged flexographic media includes the steps of illuminating said imaged flexographic media with a first illumination source that is positioned above said imaged flexographic media, and illuminating said imaged flexographic media with a second illumination source that is positioned below said imaged flexographic media.
